(19) United States
(12) Patent Application Publication
(10) Pub. No.: US 2009/0252347 A1
(43) Pub. Date: Oct. 8, 2009

(54) Method and Apparatus For Automatic Gain Control

(76) Inventors: Srinath Kakkeri, Hyderabad (IN); Mahabaleshwara R. Bhatt, Bangalore (IN); Sridhar Gurram, Andbra pradesh (IN); Mazhar K.U Sameullah, Chennai (IN); Narsinga Rao Chella, Hyderabad (IN)

Correspondence Address: ADVANCED MICRO DEVICES, INC.;C/O VEDDER PRICE P.C., 222 N.LASALLE STREET, CHICAGO, IL, 60601, US

(21) Appl. No.: 12/125,638

(22) Filed: May 22, 2008

(30) Foreign Application Priority Data
Apr. 7, 2008 (IN) 867/CHE/2008

(51) Int. Cl. H03G 3/00

(52) U.S. Cl. 381/107

(57) ABSTRACT

A method and apparatus for Automatic Gain Control (AGC) that provides an output signal having a smooth gain variation for any input signal. The various embodiments assure that the output signal will reach a required output level in a specified attack or decay period. A curvilinear reference gain characteristic is applied to the gain variations. One example uses an exponential curve and sets an initial and final value of the gain law for both attack and decay periods as presets. The various embodiments further compute intermediate gain values of the curvilinear paths that archives the smooth variations is also proposed. Other possible curvilinear characteristics may be used such as, but not limited to, logarithmic, hyperbolic, sinusoidal, etc. that are expressible as exponentials. Intermediate gain values may be determined either by table lookup or by on the fly computation of the curvilinear characteristic.

### FIELD OF THE DISCLOSURE

The present disclosure is related to methods and apparatuses for Automatic Gain Control (AGC) of audio signals and various devices, such as communications devices, that incorporate such AGC methods and apparatuses for controlling the gain applied to the audio signals.

### BACKGROUND

Usually, audio signal inputs including speech signal inputs originate from different sources and therefore may have varying levels of amplitude. This is problematic for telephony as well as other applications because a listener may experience an undesirable increase in volume level corresponding to an input signal having a high level of amplitude. Sudden decreases in volume levels are likewise undesirable.

An Automatic Gain Control (AGC) system is used to apply and maintain the needed gain dynamically to the speech/audio signals according to the specifications of the chosen audio playing or rendering equipment, for example a video telephone, speaker phone, mobile telephone, etc. An AGC system should be designed to pre-determine the specified level of amplitude dynamically without any sacrifice in audio/speech quality.

Thus for AGC systems in general, the dynamic range of the gain applied must be within the given specification of an audio rendering or playing equipment to be fed. The gain must be either incremented or decremented according to specific laws (a “gain law”) that prevents possible distortions in the quality of the speech due to, for example, amplitude variation. Further, an AGC system should prevent an excessive gain increment during prolonged intervals of silence as may exist in any speech/audio signal.

Existing AGC systems utilize gain characteristics that are based primarily on a linear characteristic. For such linear based AGC systems, the gain steps applied are either constant or increased or decreased based on empirical settings, that is, settings that have been developed over time via experimentation. None of the known linear based AGC systems appear to consider the various design requirements/considerations together, for example the dynamic range, distortion prevention and silence/noise intervals, to achieve smooth variations in the gain characteristics.

FIG. 1 illustrates the functional behavior of known AGC systems which are best explained with respect to decay, attack and hold periods. Thus FIG. 1 depicts instantaneous gain variations between an input signal 101 and an output signal 109 for decay periods 115, 123, attack periods 117, 129 and hold periods 119, 121. An “attack period” represents an interval of time in which the AGC system must respond to the input signal 101 as it increases in amplitude. The AGC system in this case must reduce the gain in order to bring the output signal 109 level to the threshold 113. A “decay period” represents an interval of time in which the input signal 101 decreases and therefore the AGC system must increase the gain to bring the output signal 109 to the threshold 113.

During decay period 115, the input signal 101 is at a low level as shown by its level with respect to the full scale (FS) vertical amplitude axis 111. The vertical amplitude along the vertical amplitude axis 111 is expressed in decibels full scale (dBFS) but is shown in FIG. 1 without specific units for simplicity of explanation. For the decay period 115 example, the gain characteristic 103 is incremented along a linear path 117 towards the preset maximum value gₘₐₓ 107. The preset maximum value gₘₐₓ 107 and the preset minimum value gₘᵢₙ 105 are specific to the audio equipment employed. If the gain reaches gₘₐₓ 107 within decay period 115 (t₀ to t₁), the gain characteristic 103 then remains constant until the beginning of the attack period 117.

During the attack period 117, which represents a sudden increase in the input signal 101 amplitude, the gain characteristic 103 must decrement linearly towards the minimum preset value gₘᵢₙ 105. The slope of the gain characteristic 103 during the attack period 117 depends on the initial time t₂ and final time t₄ of the attack period 117.

During hold period 119 and hold period 121, which follows the ends of the attack period 117 and attack period 129, respectively, the gain characteristic 103 is held constant. For example, after the brief attack period 129, the gain is held constant during hold period 121 and does not increase again until the decay period 123.

FIG. 1 also illustrates parameters that are normally user selectable or programmable such as the attack threshold θₐ 113 and the decay and attack times which may be specified in milliseconds (ms). A clipping threshold (not shown) may also be programmable.

### BRIEF DESCRIPTION OF THE DRAWINGS

FIG. 1 is a graphical illustration of the functional behavior of known AGC systems with respect to various decay, attack and hold periods.

FIG. 2 is a block diagram of a communication device such as a telephony device having a multimedia processor and an Automatic Gain Control (AGC) system of the embodiments.

FIG. 3 is a flow chart illustrating a high level operation of an AGC module of the embodiments.

FIG. 4 is a flow chart illustrating further details of operation of an AGC module of the embodiments.

FIG. 5 is a flow chart providing further details of operation with respect to the flowchart of FIG. 4.

FIGS. 6, 7 and 8 are flowcharts providing operation details of an AGC system of an embodiment.

FIG. 9 illustrates the functional behavior of an AGC system of the embodiments with respect to a gain characteristic as applied to an audio input signal.

FIG. 10 is a graph of an AGC reference gain characteristic for attack mode in accordance with an embodiment.

FIG. 11 is a graph of an AGC reference gain characteristic for a decay mode in accordance with an embodiment.

### DETAILED DESCRIPTION

A method and apparatus for Automatic Gain Control (AGC) that provides an output signal having a smooth gain variation for any input signal is disclosed herein. The various embodiments assure that the output signal will reach a required output level in a specified attack or decay period. A curvilinear reference gain characteristic is applied to the gain variations. One example uses an exponential curve and an initial and final value of the gain law for both attack and decay periods as presets. The various embodiments further compute intermediate gain values of the curvilinear paths to achieve the smooth variations in output signal level. Other possible curvilinear characteristics may be used such as, but not limited to, logarithmic, hyperbolic, sinusoidal, etc. that are expressible as exponentials. Intermediate gain values may be determined either by table lookup or by on the fly computation of the curvilinear characteristic.

To facilitate the description of the various embodiments, the following abbreviations and symbolic parameters are used throughout the description and are defined herein as follows:
G_{Max}: Maximum gain of an AGC subsystem
G_{Min}: Minimum gain of an AGC subsystem
tₛ: Sampling period in milliseconds
N: Frame size representing the grouping of the input samples that are required to have common gain
Tₐ: Attack Time in milliseconds for an AGC subsystem to reduce the gain in attack mode so that the given output reaches the attack threshold value.
T_{d}: Decay Time in milliseconds for an AGC subsystem to increment the gain in decay mode so that the given output reaches the attack threshold value
Tₕ: Hold period between end of attack period and beginning of decay
Nₐ=Number of Attack frames

$$( \frac{{T}_{α}}{{t}_{s} \times N} )$$

Number of Decay frames

$$( \frac{{T}_{d}}{{t}_{s} \times N} )$$

Nₕ=Number of Hold frames

$$( \frac{{T}_{h}}{{t}_{s} \times N} )$$

θₐ: Threshold value to initiate the attack mode if given output signal level exceeds this value.
θ_{c}: AGC subsystem clips the output to this value if the output exceeds this clip level value.
δ: Permissible deviation in +/− percentage with respect to final settling value.
gₐ: Gain of the reference curve in attack mode
fₐ: Factor by which the current gain is less with respect to previous gain
g_{d}: Gain of the reference curve in decay mode
f_{d}: Factor by which the current gain is more with respect to previous gain
g(i): Gain variable of the reference exponential gain characteristics
G(i): Actual gain variables to be calculated

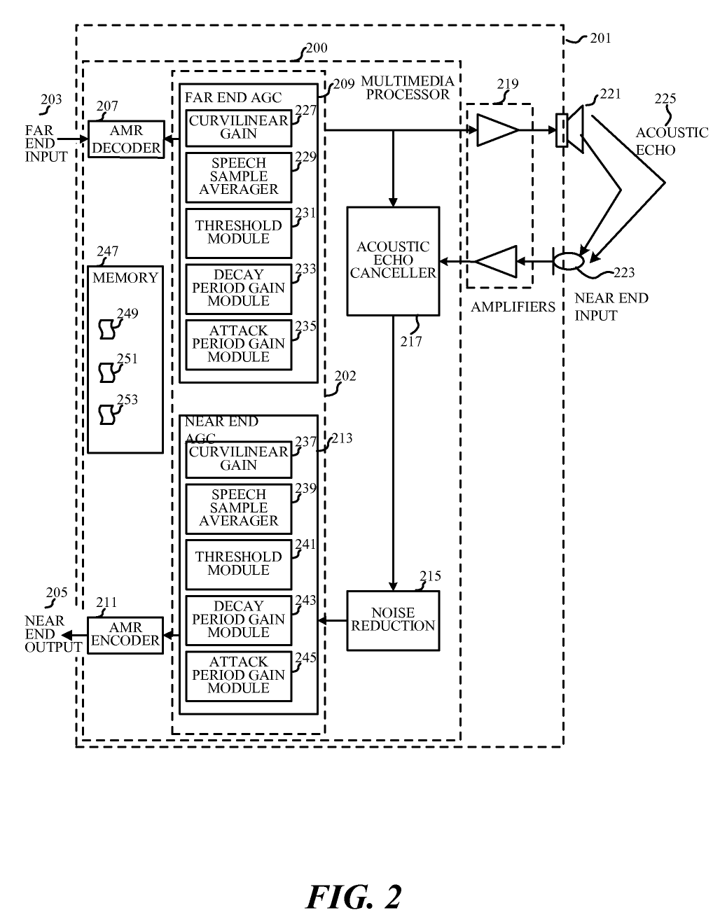

FIG. 2 illustrates one possible embodiment of the AGC wherein the AGC is embodied within a multimedia processor 200. The multimedia processor 200 is incorporated within a video telephony device 201 or other communication device. It is to be understood that the illustration provided by FIG. 2 is exemplary only and is for exemplifying one possible embodiment within which the AGC may be incorporated. However, FIG. 2 is not intended to be a complete schematic diagram and is only for the purpose of illustrating the incorporation of an AGC system within a multimedia processor or other implementations in accordance with the embodiments. As would be understood by one of ordinary skill many other components may be necessary in order to form a complete schematic diagram of the video telephony device 201. However such components and their associated connections are omitted from FIG. 2 to facilitate simplicity of illustration and simplicity of description of the embodiments illustrated. Therefore FIG. 2 is for example purposes only and is not to be construed as a complete schematic diagram. Further FIG. 2 is not to be construed as a limiting factor as to the possible applications of the AGC in other embodiments, such as, but not limited to, mobile phones, speaker phones, desktop computing equipment, laptop computers, etc., or any other suitable device. Further, a device employing the herein described AGC may provide an audio signal output in “real time” for example, during a phone call or conference call, or may store an audio signal output in memory for later retrieval and listening.

Thus the video telephony device 201 as illustrated in FIG. 2 receives a far end input signal 203 which may be received from a network connection for example a wire line connection or via a wireless network connection or any other suitable connection. Likewise the video telephony device 201 provides a near-end output 205 which may be transmitted via the same network as the input, or may be sent via another network, such as, but not limited to, a wire line telephone connection or a wireless telephony connection, a cable broadband connection or any other suitable connection as would be understood by one of ordinary skill.

The far end input 203 is processed by a decoder 207 which may be for example, an adaptive multi-rate (AMR) decoder. However any suitable decoder may be employed. The decoder output is coupled to a far end automatic gain control (AGC) module 209 of an overall AGC module 202. The AGC module 202 therefore may, in some embodiments consist of the far end AGC module 209 and a near-end AGC module 213. However, any suitable configuration may be employed; for example, the far end AGC module 209 may be physically separate from the near end AGC module 213 in some embodiments.

The far end AGC module 209 is further coupled to amplifiers 219 for the purpose of providing an output signal to, for example, speaker 221. Likewise the near end AGC module 213 is coupled to a noise reduction module 215 which is further coupled to an acoustic echo canceller 217. The acoustic echo canceller 217 receives a near end input signal from microphone 223 and amplifiers 219. The input signal to the amplifiers 219 may be produced by other suitable devices alternatively, or in addition to the microphone 223.

As shown in FIG. 2 the speaker 221 and microphone 223 may form an acoustic echo 225 by coupling to each other as shown. Therefore, in the various embodiments an acoustic echo canceller 217 may be employed. The far end AGC module 209 likewise is coupled to the acoustic echo canceller 217, for the purpose of reducing the acoustic echo 225 between the speaker 221 and the microphone 223.

In accordance with the embodiments the far end AGC module 209 and the near end AGC module 213 forming the overall AGC module 202 both have attack and decay gain characteristics based upon a curvilinear function. Therefore, in some embodiments, far end AGC module 209 may further include a curvilinear gain module 227, a speech sample averager 229, a threshold module 231, a decay period gain module 233 and an attack period gain module 235. Likewise the near end AGC module 213 may further include a curvilinear gain module 237 a speech sample averager 239, a threshold module 241, a decay period gain module 243 and an attack period gain module 245.

The curvilinear gain modules 227, 237 compute initialization values and perform determination of attack and decay gain characteristics based on a number of audio attack and decay frames, an applicable sample rate and based upon a non-linear curvilinear function. The gain determinations may be made based upon computations or may be made using a lookup table 249 stored in memory 247 where the memory is coupled to, and accessible by, the far end AGC module 209 and the near end AGC module 213.

The memory 247 may also store empirically determined parameters 251 for use in initialization. The memory 247 may also store the code 253 for implementing the AGC processes on the multimedia or other processor 200 and by the AGC module 202. It is to be understood that the memory 247 may be integrated with the processor 200, or with the AGC module 202 or may be a separate component coupled to the processor 200 or to an AGC module 202. Therefore, any configuration or arrangement of components that provides the AGC system as herein described remains in accordance with the embodiments.

It will also be appreciated that AGC calculations and otherwise any processing of received signals may be performed in a dedicated device such as a receiver having a dedicated processor, a processor coupled to an analog processing circuit or receiver analog “front-end” with appropriate software for performing a receiver function, an application specific integrated circuit (ASIC), a digital signal processor (DSP), or the like, or various combinations thereof, as would be appreciated by one of ordinary skill. Therefore, any appropriate logic may be employed for the various embodiments wherein the logic may include one or more of hard wired circuits, processors, an ASIC, a DSP, etc. Memory devices such as memory 247 and/or processors such as processor 200 may further be provisioned with routines and algorithms for operating on input data and providing output such as operating parameters to improve the performance of the amplifiers and/or other processing blocks associated with, for example, reducing noise and echo, and otherwise appropriately handling the input signals.

The inventive functionality and inventive principles herein disclosed may be implemented with or in software or firmware programs or instructions and integrated circuits (ICs) such as digital signal processors (DSPs) or application specific ICs (ASICs) as is well known by those of ordinary skill in the art. Therefore, further discussion of such software, firmware and ICs, if any, will be limited to the essentials with respect to the principles and concepts used by the various embodiments.

Additionally, any of the various modules herein described may also be implemented via software or firmware programs or instructions and integrated circuits (ICs) such as digital signal processors (DSPs) or application specific ICs (ASICs) or by any appropriate logic wherein the logic may include one or more of hard wired circuits, processors, an ASIC, a DSP, etc. and/or software and firmware programs or instructions that may be run on such modules.

It will further be appreciated that devices such as video telephony device 201 are exemplary only and may refer to various other devices such as cellular or mobile phones, two-way radios, messaging devices, personal digital assistants, personal assignment pads, personal computers equipped for wireless operation, a cellular handset or device, or the like, or equivalents thereof provided such units are arranged and constructed for operation in accordance with the various inventive concepts and principles embodied in exemplary AGC systems herein described, and methods for, among other things, utilizing a curvilinear function to determine an attack period gain and a decay period gain as discussed and described herein.

The speech sample averagers 229, 239 compute an average amplitude of a set of speech samples to be used for comparison with threshold values by threshold module 231, 241 to determine whether the input signal represented by the set of speech samples, is in an attack period or a decay period. The attack or decay determination is then used to route the process to either the decay module 233, 243 or the attack module 235, 245 as appropriate, to determine the gain to apply.

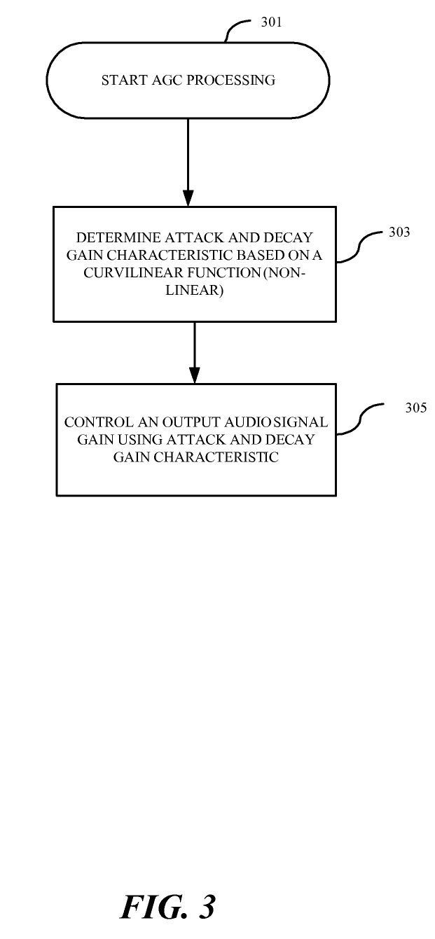

Turning now to FIG. 3 a high level operation of the AGC module 202 is illustrated. In 301 the AGC system may be initialized using empirically determined parameters. As shown in FIG. 2, the empirically determined parameters 251 may be stored in memory for use in initialization. The empirically determined parameters may be obtained in various ways, for example, the parameters, or applicable ranges for the parameters, may be determined by the specifications of the audio amplifiers or other equipment used in a device, for example, video telephony device 201. Alternatively, or in addition, the parameters may be obtained through engineering experience with various types of audio devices or via experimentation and observation, that is, trying various settings and observing the resulting audio quality for a specific device. In any such scenario, the parameters, once determined, may then be placed in memory as shown in FIG. 2, for use by the embodiments in 301. In 303 the AGC module 202 determines the attack and the decay gain characteristics based on a curvilinear function which is a nonlinear function. In 305, an audio output signal is controlled using the appropriate gain characteristic, that is, either the attack or decay characteristic applied at appropriate time intervals of the audio output.

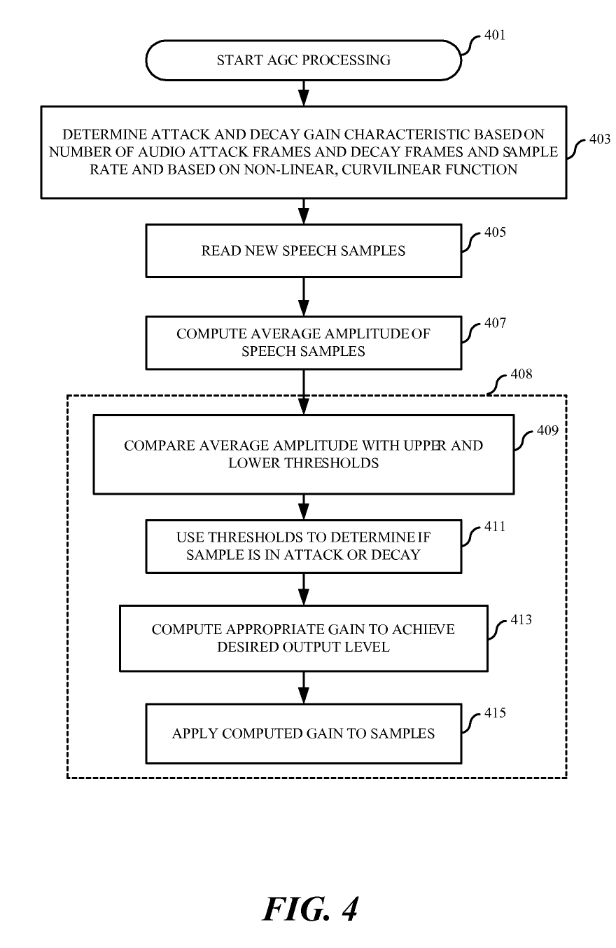

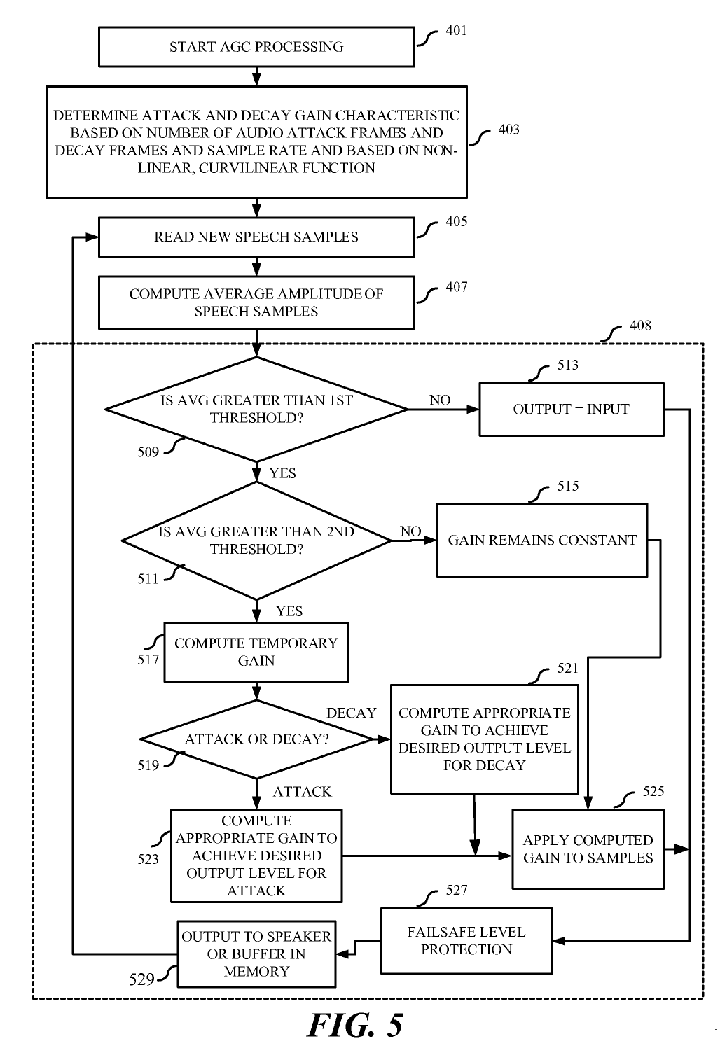

FIG. 4 is a flow chart illustrating further details of AGC module 202 operation. Thus in 401, the AGC system may initialize using empirically determined parameters. Block 401 provides some exemplary values for the empirically determined parameters which are for purposes of illustration only. The exemplary values may be appropriate for example, for use in a video telephony device and application, however it is to be understood that various considerations, such as, but not limited to, equipment specifications, application, etc., may be a factor in determining the appropriate settings. In 403 the AGC determines the attack and decay gain characteristics based on a number of audio attack frames, audio decay frames, a sample rate and also a nonlinear curvilinear function. In 405 a new set of speech samples is read into the AGC system. In 407, an average amplitude of the speech samples is computed. The AGC module 202 then continues with the processing 408 which is illustrated in FIG. 4 at a high level and explained in further detail in the following figures such as FIG. 5.

Thus the high level operation of 408 may be described as follows. In 409 the average amplitude is compared with an upper and lower threshold. The upper and lower threshold parameters are determined for example, as shown in block 403. In 411 the AGC system uses the threshold values to determine if the speech sample is in an attack period or in a decay period. In 413, the AGC module 202 computes an appropriate gain to achieve a desired output level in light of whether the signal is in an attack or decay period. In 415 the gain is applied to the speech samples to produce the output signal.

As previously mentioned FIG. 5 provides additional details of the operations shown in FIG. 4 and particularly with respect to processing 408. Thus in 509, the AGC module 202 determines whether the amplitude of the speech samples is greater than a first threshold. If not, then in 513 the output signal level is set equal to the input signal level. However if the average amplitude of the speech samples is greater than the first threshold in 509, the processing 408 moves to block 511 which compares the average amplitude of the speech samples to a second threshold level.

If the second threshold is not exceeded then the gain remains at a constant level as shown in block 515. However if the average of the amplitude of the speech samples is greater than the second threshold a temporary gain value is computed as shown in block 517. Note that the gain computation accomplished in block 517 is independent of whether the input signal is in attack period or in a decay period. Therefore subsequently, as shown in 519, a determination is made as to whether the signal is indeed in an attack period or in a decay period.

If in 519 it is determined that the input signal is in a decay period then appropriate gain is computed to achieve the desired output level for that decay period as shown in 521. However if the signal is found to be in attack period then as shown in block 523 an appropriate gain is computed to achieve the desired output level given that the input signal is in an attack period. In block 525, the appropriate gain as computed is applied to the samples of the input signal.

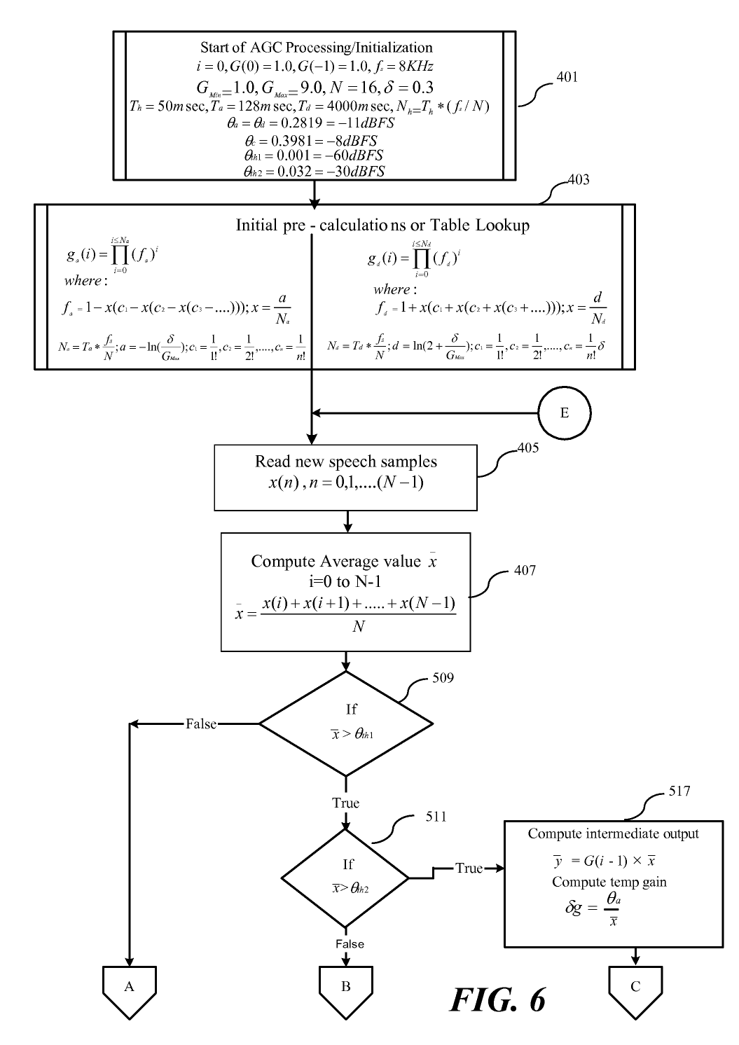

In 527 a fail safe level protection may be also applied to the input signal to, for example, accommodate a saturation level of the amplifiers. Therefore by fail safe level protection 527, the electronic equipment is protected from possible damage. In 529, the output signal is applied to the speaker or alternatively, may be buffered in memory. At that point the process returns to block 405 where a new set of speech samples is read. FIGS. 6, 7 and 8 and the following description provides additional details as to the computations accomplished within the various blocks of FIGS. 3, 4 and 5.

For the AGC system of the embodiments, various user selectable, that is, programmable parameters are employed including; an attack threshold (θₐ in dBFS), a clipping threshold (0, in dBFS), decay time and attack time (both in msec).

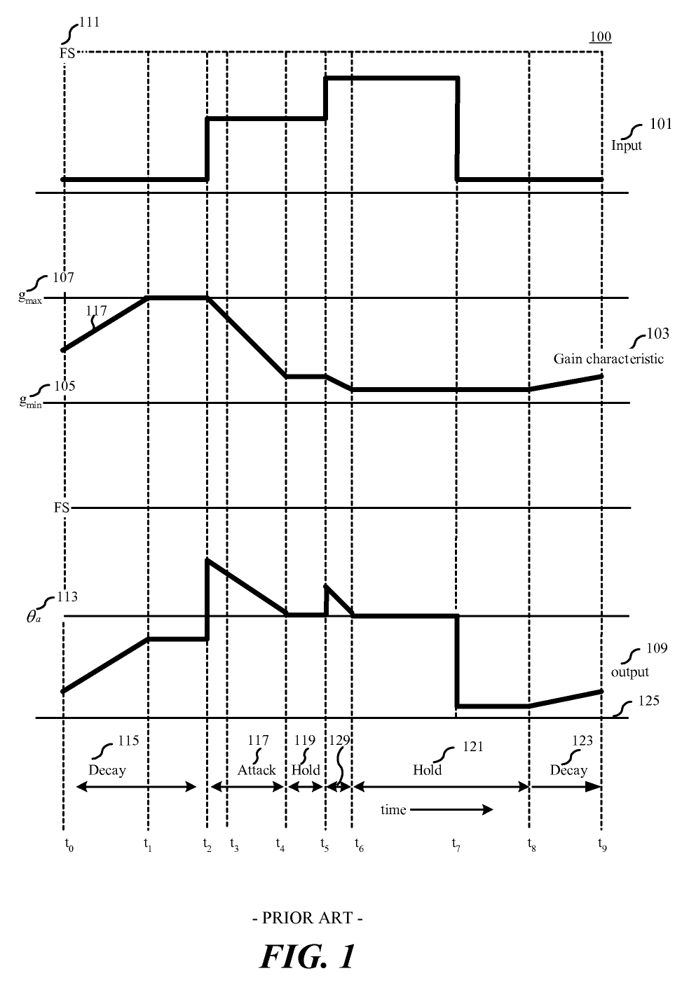

In contrast to existing AGC systems as described with respect to FIG. 1, the presently disclosed AGC system takes into account among other considerations, dynamic range, distortion prevention and silence/noise intervals in an input signal, to achieve smooth variations in the gain characteristics. Better performance in quality of the speech/audio signal after dynamic automatic gain processing is thereby achieved by the various embodiments.

The reference gain characteristics applied by the various embodiments are based on a curvilinear law that not only generalizes the required gain decrements and increment during attack and decay periods respectively, but also may incorporate a linear type of characteristic, as exemplified by FIG. 1, as a special case.

For illustration and with respect to FIGS. 6, 7 and 8, an exponential characteristic is used to exemplify a curvilinear characteristic in accordance with the embodiments. However, it is to be understood that an exponential characteristic is used here as an example only, and to facilitate understanding of the various embodiments by one or ordinary skill. Therefore, in the embodiments, any curvilinear characteristic/law that may be expressed as any form involving an exponential such as, but not limited to, hyperbolic, logarithmic and/or trigonometric, etc., may be utilized as a gain characteristic, or as a component of a gain characteristic, and would remain in accordance with the embodiments herein described.

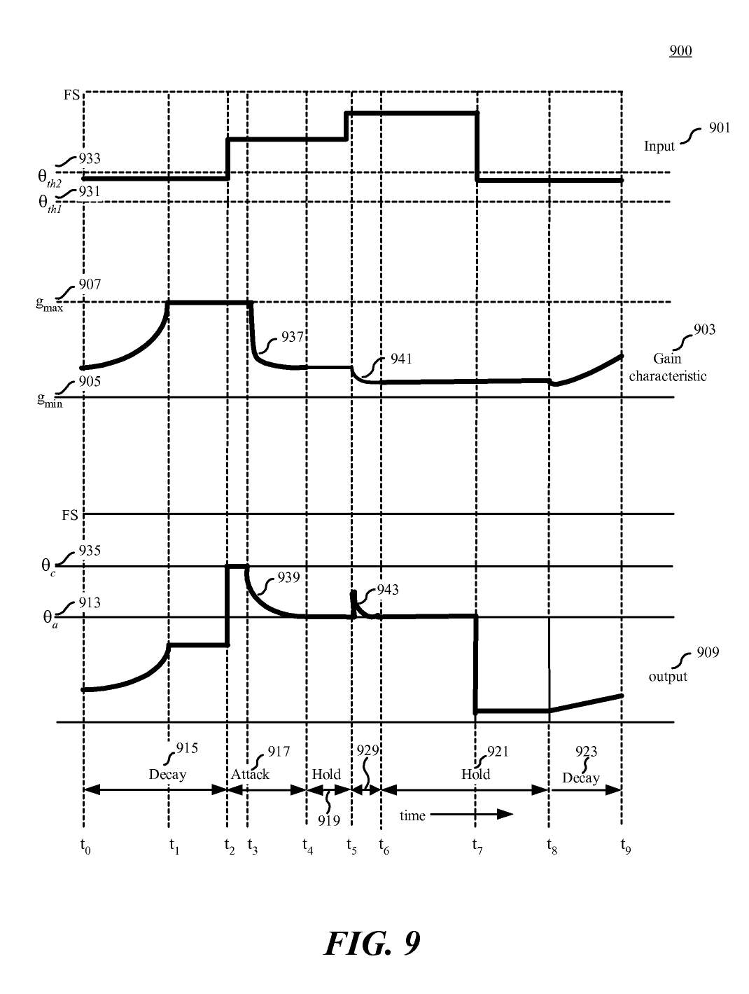

The gain characteristics for various attack, decay and hold periods, in accordance with the embodiments are illustrated in FIG. 9, and will be described in further detail by FIGS. 6, 7 and 8. Although some values are provided for the various parameters and computations involved, it is to be understood that such values are provided as exemplary only to facilitate understanding of the embodiments by one of ordinary skill. Therefore, none of the values provided herein are to be construed as a limitation on the embodiments. Any values may be used that are appropriate for a given application and/or for a given type of apparatus/equipment making use of the embodiments herein described.

Therefore, an example of operation of the embodiments is illustrated beginning with FIG. 6 wherein in 601, AGC processing begins. In 401, initialization of various parameters is performed, thus for example: G(0)=1.0, G(−1)=1.0, fₛ=8 KHz. G_{Min} and G_{Max} are set as G_{Min}=1.0 and G_{Max}=9.0.

Variable to used as indices may be initialized for example, as i=0, Nₐ=0 and N_{d}=0. Further, various parameters may be chosen such as an attack threshold “θₐ” (in decibels full scale dBFS), a clipping threshold “θ_{c}” (in dBFS), a hold time “Tₕ” (in ms), a decay time “T_{d}” (in ms) and an attack time “Tₐ” (in ms). Exemplary values for these parameters are as follows: N=16, θₐ=0.2819=−11 dBFS, θ_{c}=0.3981=−8 dBFS, Tₕ=50 ms, Tₐ=128 ms, T_{d}=4000 ms.

In 403, initial pre-calculations are performed as follows:

Compute Nₐ:

$${N}_{a} = \frac{{T}_{a}}{N \times {t}_{s}} \qquad ( 1 )$$

Considering the reference gain characteristic of the AGC system as exponential in nature, the computation of the exponential gain characteristic and its instantaneous values during the attack period Tₐ can be viewed as:

$${g}_{a} ( i ) = {\prod }_{i = 0}^{i \leq {N}_{a}} {( {exp}^{- \frac{a}{{N}_{a}}} )}^{i} \qquad ( 2 )$$

where,

$$a = - ln ( 0 + \frac{δ}{{G}_{Max}} ) ,$$

and δ is a small deviation with respect to the final desired value. Instead of selecting the typical minimum value as 0 for at time instant index i=Nₐ, the various embodiments utilize

$$” 0 + \frac{δ}{{G}_{Max}} ” ,$$

by noting that the gain characteristic converges asymptotically to zero. A typical deviation δ with respect to final desired level is usually taken around 3 percentage instead of 0. On choosing allowable maximum gain variation as 1 and further letting

$${f}_{a} = {exp}^{- \frac{a}{{N}_{a}}} ,$$

the expression for gₐ(i) may be viewed as:

$${g}_{a} ( i ) = {\prod }_{i = 0}^{i \leq {N}_{a}} {( {f}_{a} )}^{i} \qquad ( 3 )$$

Calculating the exponential form fₐ:
   Using Taylor's series and Horner's rule, fₐ may be expressed as:

$$\begin{matrix}{f}_{a} = 1 = x ( {c}_{1} = x ( {c}_{2} = x ( {c}_{3} = x ( {c}_{5} - … ) ) ) ) ) \\ Where , & ( 4 ) \\ x = \frac{a}{{N}_{a}} , \\ {c}_{1} = \frac{1}{1 !} , {c}_{2} = \frac{1}{2 !} , {c}_{3} = \frac{1}{3 !} … , {c}_{n} = \frac{1}{n !} . & ( 5 )\end{matrix}$$

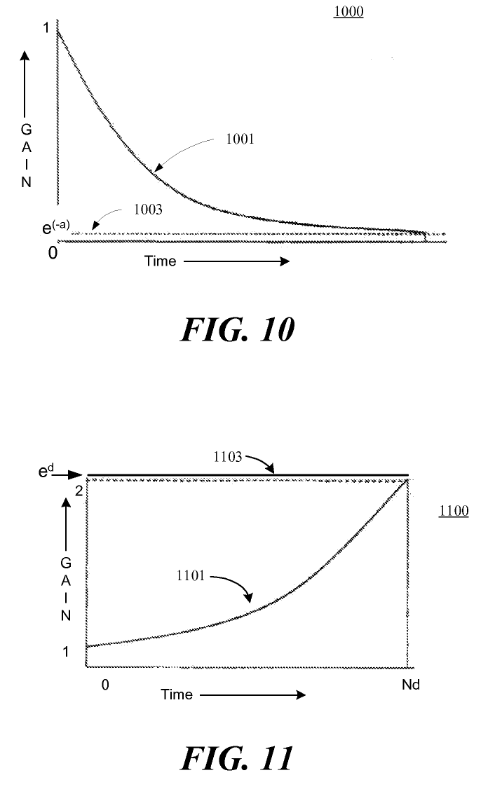

On using Taylor's series expansion given in equation (4), the reference exponential gain may be expressed in equation (3) and may be computed dynamically during the remaining steps of the algorithm. Typically, 10 coefficients are sufficient to compute fₐ. Mainly, equation (2) gives the procedure to calculate the reference gain at any instant of time 0 through Nₐ. An example of a gain characteristic for attack mode in accordance with the embodiments is illustrated in FIG. 10.

The computations of 403 in FIG. 6 continue by computing N_{d} as follows:

$${N}_{d} = {T}_{d} \times \frac{{f}_{s}}{N} \qquad ( 6 )$$

The decay reference gain characteristic of the AGC system of the embodiments may have the exponential nature as exemplified by FIG. 11. Similar to the case for an attack period, the computation of the exponential gain characteristic and its instantaneous value during the decay period can be viewed as:

$${g}_{d} ( i ) = {\prod }_{i = 0}^{i \leq {N}_{d}} {( {exp}^{\frac{d}{{N}_{d}}} )}^{i} \qquad ( 7 )$$

Instead of selecting the typical minimum and maximum value as 0 and 1 at time instant index i of zero and N_{d}, the various embodiments choose 1 and

$$2 + ( \frac{δ}{{G}_{Max}} ) ,$$

as gain characteristic asymptotically approaches 2. The typical δ with respect to final desired gain is usually around 3 percentage. Letting, the expression for

$${f}_{d} = {exp}^{( \frac{d}{{N}_{d}} )} ,$$

g_{d} may be viewed as:

$${g}_{d} ( i ) = {\prod }_{i = 0}^{i \leq {N}_{d}} {( {f}_{d} )}^{i} \qquad ( 8 )$$

Calculating the exponential form f_{d}:
   Using Taylor's series and Horner's rule, f_{d} may be expressed as:

$$\begin{matrix}{f}_{a} = 1 = x ( {c}_{1} = x ( {c}_{2} = x ( {c}_{3} = x ( {c}_{5} - … ) ) ) ) ) \\ Where , \\ x = \frac{d}{{N}_{d}} , d = ln ( 2 + \frac{δ}{{G}_{Max}} ) \\ {c}_{1} = \frac{1}{1 !} , {c}_{2} = \frac{1}{2 !} , {c}_{3} = \frac{1}{3 !} … , {c}_{n} = \frac{1}{n !} .\end{matrix} \qquad ( 9 )$$

On substituting equation (9) in equation (8), the reference exponential gain may be computed dynamically during the remaining steps of the algorithm. Typically, 10 coefficients are sufficient to compute f_{d}. Mainly, equation (8) gives the procedure to calculate the reference gain at any instant of time index i=0 through N_{d}. An example of a gain characteristic for decay mode in accordance with the embodiments is illustrated in FIG. 11.

In 405, new speech samples are input x(n), n=0, 1, (N−1) and form the current frame. For the embodiments, the Frame size, N is chosen based on the required smoothness in accordance with the gain characteristics shown in FIG. 10 and FIG. 11. For example, N may be 16.

In 407, an average value x̅ is computed for the above formed frame as:

$$\overline{x} = \frac{1}{N} {\sum }_{n = 0}^{N - 1} \vert x ( n ) \vert \qquad ( 10 )$$

Where, “| |” represents the absolute value of x(n). In 509 and 511 the computed average value is compared with thresholds.

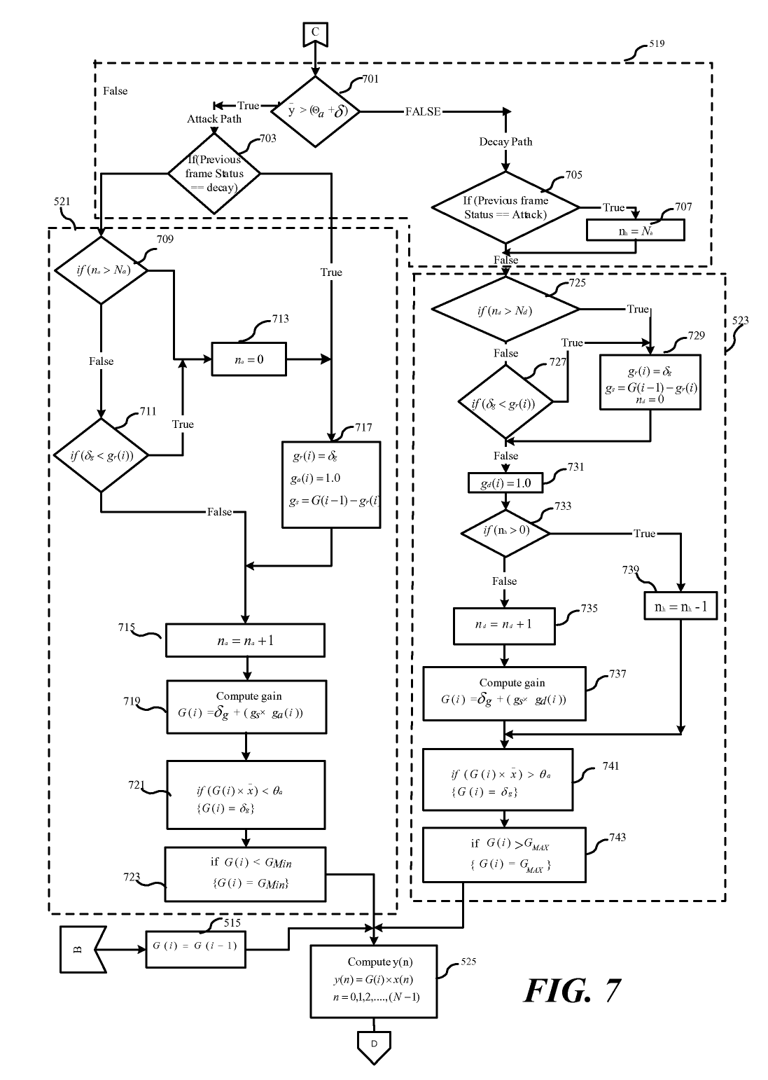

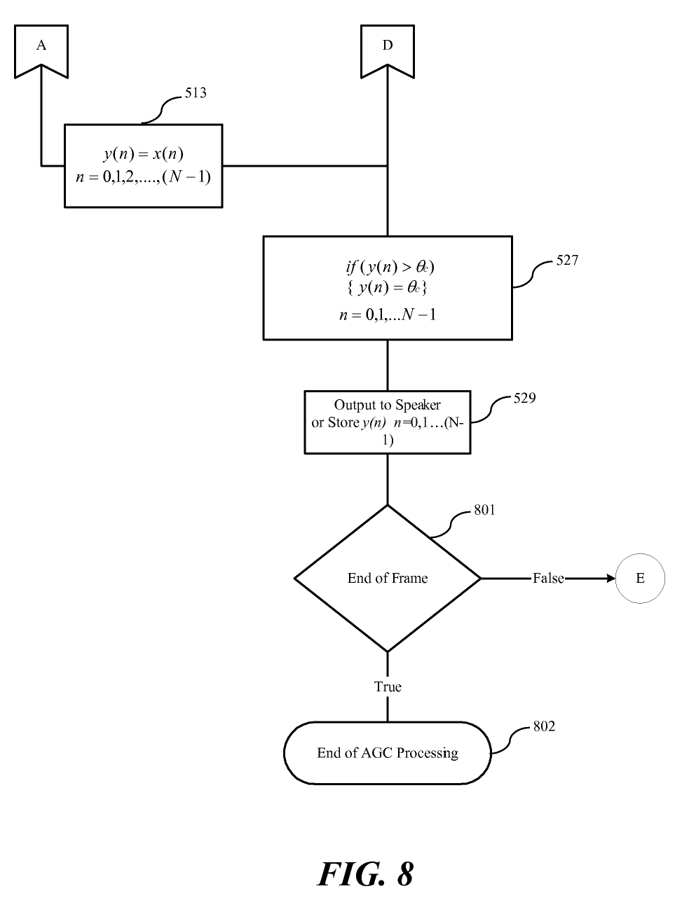

If x̅≦θₜₕ₁, that is, if the result of 509 is false, the process continues via connection “A” to 513 of FIG. 8, and proceeds to set y(n)=x(n), where n=0, 1, - - - , (N−1). In other words, the output level is set equal to the signal input level. The process in this case will then proceed to the failsafe level protection block 527 of FIG. 8. If 509 is found true and 511 is found false, that is, if θₜₕ₁< x̅≦θₜₕ₂, then the process continues to connection “B” of FIG. 7 and thus to block 515 which proceeds to set G(i)=G(i−1). That is, the gain applied to a current frame of samples is the same as the gain applied to a previous frame of samples, which in other words maintains the gain at a constant level.

Returning to FIG. 6 and block 511, if x̅>θₜₕ₂, that is, if the result of 511 is true, then the process proceeds to 517 and sets y̅=G(i−1)× x̅, and computes δ_{g}=θₐ/ x̅.

For the various embodiments, the parameter θₜₕ₁ is selected based on the perceivable human hearing level and may be for example therefore, around θₜₕ₁=−60 dBFS. The parameter θₜₕ₂ is selected mainly to control the perceivable distortion during the transition from a long tail of low level speech in a signal to a sharp raise in a leading edge of a speech signal to make sure that excessive gain is not applied during these instances. An exemplary value for θₜₕ₂ is about −30 dBFS.

From block 517 the AGC process continues via connection “C” and onto block 701 of FIG. 7. Blocks 701, 703, 705 and 707 make up block 519 shown on FIG. 5, wherein a determination is made of whether an input signal is in an attack or decay period. Thus if the result of block 701 it true, that is, if y̅>(θₐ+δ), then the input signal is in an attack period and the process proceed to block 703.

The following description provides further details of the processing of block 523 illustrated in FIG. 5. Thus in block 703, if the previous frame status=“decay,” that is, if the result of block 703 is true, then the process proceeds to block 717, setting gᵣ(i)=δ_{g}, gₐ(i)=1.0 and computing gₛ=G(i−1)−gᵣ(i).

In block 703, if the previous frame status does not equal “decay,” that is, if the result of block 703 is false, then the process proceeds to block 709. If the result of block 709 if false, that is, if nₐ<Nₐ, then the process checks if δ_{g}<gₐ(i) in block 711. If nₐ<Nₐ and δ_{g}<gₐ(i), that is, if block 709 is false and block 711 is true, then in block 713, the process sets nₐ=0, and further proceeds to block 717. However, if the result of block 709 is true, that is, if nₐ>Nₐ, then the process also proceeds to block 713, and sets nₐ=0.

If nₐ<Nₐ and δ_{g}>gₐ(i), that is, if block 709 is false and block 711 is also false, then in block 715, the process sets nₐ=nₐ+1 and computes G(i)=δ_{g}+(gₛ×gₐ(i)) in block 719. In 721, if G(i)× x̅<θₐ, then G(i)=δ_{g}, otherwise the process continues past block 721, and in block 723 if G(i)<G_{Min}, then the process sets G(i)=Gₘᵢₙ, otherwise, the process continues past block 723 to block 525 wherein the computed gain is applied to the samples.

Returning to block 701, and where the determination is made of whether an input signal is in an attack or decay period, if the result of block 701 it false, that is, if y̅≦(θₐ+δ), then the input signal is in a decay period and the process proceeds to block 705.

If previous frame status in block 705 is “attack,” such that the result of block 705 is true, then the process moves to block 707 and sets nₕ=Nₕ. After block 707, or if the result of block 705 is false, then the process moves to block 725. In block 725, if the result is false, that is, if n_{d}≦N_{d} the process moves to block 727 and checks δ_{g}. If the result of block 727 is also false, that is, if n_{d}≦N_{d} in block 725 and if δ_{g}≧gᵣ(i) in block 727, then in block 731 the process sets g_{d}(i)=1.0.

In block 725, if the result is true, that is, if n_{d}>N_{d} the process moves to block 729 and sets gᵣ(i)=δ_{g}, computes gₛ=G(i−1)−gᵣ(i) and sets n_{d}=0. If the result of block 725 is false and the result of block 727 is true, that is, if n_{d}≦N_{d} and δ_{g}<gᵣ(i) the process also moves to block 729 sets gᵣ(i)=δ_{g}, computes gₛ=G(i−1)−gᵣ(i) and sets n_{d}=0. After block 729 the process move to block 731 and sets g_{d}(i)=1.0.

If nₕ>0 in block 733 then in block 739 the process sets nₕ=Nₕ−1 and proceeds to block 741. However, if the result of block 733 is false, that is, if nₕ≦0, the in block 735 the process sets n_{d}=n_{d}+1 and computes the gain G(i)=δ_{g}+(gₛ×g_{d}(i)). After block 737 or 739 the process continues in block 741 and checks if (G(i)× x̅)>θₐ and if so, sets G(i)=δ_{g}. Otherwise, the process continues with block 741, checks if G(i)>G_{Max} and if so, sets G(i)=G_{Max}. Otherwise the process continues to block 525 and applies the gain to the samples to obtain an output signal as y(n)=G(i)×x(n), where n=0, 1, 2, . . . , (N−1). The process then continues to block 527 of FIG. 8 via connection “D.”

If in block 527, y(n)>θ_{c}, that is, if the clipping threshold is exceeded, then the process sets y(n)=θ_{c}, where n=0, 1, 2, . . . , (N−1). In 529 the output may be provided to a speaker, using appropriate digital-to-analog conversion processing or circuitry, or may be stored in memory, for example memory 247 as y(n), where n=0, 1, . . . (N−1).

At that point, the process checks whether the end of the speech/audio frame has been reached in 801 and if so, the AGC processing ends in 802. However if the frame continues then process continues via connection “E” which returns to block 405 of FIG. 6 to read in another set of speech/audio samples.

Additionally, the above described exemplary embodiment is able to improve the crest factor with respect to an input speech/audio signal. The crest factor may be defined as the ratio between the peak value of an input signal to its root mean square (RMS) value.

FIG. 9 is a graph 900 which represents an exemplary gain characteristic 903 which may be obtained by the various embodiments. As shown for attack periods 917, 929 the gain characteristic 903 exhibits corresponding smooth transitions 937, 941. This results in the correspondingly smooth audio output signal 909 transitions 939, 943. Note that the clipping threshold 935 is monitored as was discussed above with respect to block 527 of FIG. 8. FIG. 9 also illustrates the first threshold 931 and the second threshold 933 which are utilized to determine the state of the input signal (attack or decay mode) as discussed above.

FIG. 10 and FIG. 11 are graphs showing exemplary gain characteristics for attack mode and decay mode, respectively. In FIG. 10 the exponential gain characteristic curve 1001 decreases exponentially and smoothly over time and reaches the asymptote 1003, representing the desired gain level, over the number of attack frames Nₐ. For the decay mode as shown in FIG. 11, the exponential gain characteristic curve 1101 increases exponentially and smoothly to reach the desired gain asymptote 1103 over the number of decay frames N_{d}.

Therefore, methods and apparatuses for automatic gain control have been disclosed with characteristics that yield good speech/audio quality. In the embodiments disclosed, the gain is adjusted based on curvilinear gain characteristics that assure a higher slope in the beginning and that increments/decrements the slope smoothly and accordingly to whether the signal is proceeding in an attack period or in a decay period as applicable.

What is claimed is:

1. A method of automatic gain control comprising:
determining a gain characteristic based on a curvilinear function and a set of empirically determined parameters; and
controlling an output audio signal gain using said gain characteristic.

2. The method of claim 1, wherein determining a gain characteristic based on a curvilinear function further comprises:
determining a gain characteristic based on a curvilinear characteristic in an exponential form.

3. The method of claim 2, wherein determining a gain characteristic based on a curvilinear characteristic in an exponential form further comprises:
determining a gain characteristic based on at least one of: a hyperbolic function, a logarithmic function or a trigonometric function.

4. The method of claim 1, wherein determining a gain characteristic based on a curvilinear function further comprises:
calculating an initial gain value and a final gain value of said gain characteristic using said curvilinear function for an attack period and a decay period.

5. The method of claim 1, wherein determining a gain characteristic based on a curvilinear function further comprises:
performing one of: a table look up of gain characteristic values from a table corresponding to said curvilinear function, or a computation of said gain characteristic based on said curvilinear function for a decay period and an attack period.

6. The method of claim 1, further comprising:
computing an average value of an absolute sum of an input audio signal sample; and
determining an intermediate gain characteristic dynamically for identifying a gain swing and a gain value for an attack period and a decay period.

7. The method of claim 4, further comprising:
applying said gain characteristic to an audio input signal by applying an initial gain step size to said audio input signal; and
gradually decreasing or increasing said initial step size as said audio input signal approaches the end point of said attack period or an end point of said decay period.

8. The method of claim 1, further comprising:
applying a first threshold level and a second threshold level, said second threshold level being higher than said first threshold level, said first threshold and said second threshold for preventing an excessive gain application during a prolonged silence period of an input audio signal.

9. The method of claim 8, further comprising:
applying an attack threshold level and a clip threshold level.

10. The method of claim 4, further comprising:
providing a gain to said input signal such that said output audio signal reaches a required output level within at least one of a set attack time or a set decay time.

11. The method of claim 1, wherein controlling an output audio signal gain using said gain characteristic further comprises:
providing an output audio signal gain control signal to an amplifier and to an acoustic echo canceller, wherein said amplifier provides said output audio signal to at least one of: an audio speaker or a memory, and wherein said acoustic echo canceller cancels an acoustic echo occurring between a microphone and said audio speaker.

12. Automatic gain control circuitry comprising:
logic operative to determine a gain characteristic based on a curvilinear function and a set of empirically determined parameters; and
control an output audio signal gain using said gain characteristic.

13. The automatic gain control circuitry of claim 12, wherein said logic is further operative to:
determine a gain characteristic based on said curvilinear characteristic, wherein said curvilinear characteristic is in an exponential form; and
calculate an initial gain value and a final gain value of said gain characteristic using said exponential form for an attack period and a decay period.

14. The automatic gain control circuitry of claim 13, wherein said logic is further operative to:
perform one of a table look up of gain characteristic values from a table corresponding to said curvilinear function, or a computation of said gain characteristic based on said curvilinear function for a decay period and an attack period.

15. The automatic gain control circuitry of claim 14, wherein said logic is further operative to:
compute an average value of an absolute sum of a signal sample; and
determine an intermediate gain characteristic dynamically for identifying a gain swing and a gain value for said attack period and said decay period.

16. The automatic gain control circuitry of claim 14, wherein said logic is further operative to:
apply said gain characteristic to said signal sample by applying an initial gain step size to said signal;
gradually decrease said initial step size as said signal approaches the end point of said attack period or an end point of said decay period;
apply a first threshold level and a second threshold level, said second threshold level being higher than said first threshold level, said first threshold and said second threshold for preventing an excessive gain application during a prolonged silence period of said input signal;
apply an attack threshold level and a clip threshold level; and
provide a gain to said signal sample such that an output signal reaches a required output level within at least one of a set attack time or a set decay time.

17. The automatic gain control circuitry of claim 12, wherein said logic comprises:
a programmable processor and a memory;
said programmable processor being programmed to determine said gain characteristic based on said curvilinear function and said set of empirically determined parameters, wherein said empirically determined parameters are stored in said memory; and
control an output audio signal gain using said gain characteristic.

18. The automatic gain control circuitry of claim 17, wherein a telephony device comprises said automatic gain control circuitry and wherein said telephony device further comprises:
an acoustic echo canceller coupled to said programmable processor;
an amplifier circuit coupled to said acoustic echo canceller and coupled to said programmable processor;
an audio speaker coupled to said amplifier circuit;
a microphone coupled to said amplifier circuit;
and wherein said logic further comprises:
a far end automatic gain control module coupled to a decoder, for receiving an audio input signal from an external connection; and
a near end automatic gain control module coupled to an encoder, for providing an audio output signal to an external connection.

19. Memory comprising: executable instructions for execution by one or more processors, that when executed cause the one or more processors to:
determine a gain characteristic based on a curvilinear function and a set of empirically determined parameters; and
control an output audio signal gain using said gain characteristic.

20. The method of claim 19, wherein said executable instructions, when executed further cause the one or more processors to:
determine said gain characteristic based on at least one of: a hyperbolic function, a logarithmic function or a trigonometric function;
calculate an initial gain value and a final gain value of said gain characteristic using said curvilinear function for an attack period and a decay period;
perform one of: a table look up of gain characteristic values from a table corresponding to said curvilinear function, or a computation of said gain characteristic based on said curvilinear function for a decay period and an attack period;
compute an average value of an absolute sum of an input audio signal sample; and
determine an intermediate gain characteristic dynamically for identifying a gain swing and a gain value for an attack period and a decay period.
